(19) United States
(12) Patent Application Publication
(10) Pub. No.: US 2019/0326554 A1
(43) Pub. Date: Oct. 24, 2019

(54) ENCAPSULATION STRUCTURE OF ORGANIC LIGHT EMITTING DIODE AND ENCAPSULATING METHOD

(71) Applicant: Wuhan China Star Optoelectronics Semiconductor Display Technology Co., Ltd., Wuhan (CN)

(72) Inventor: Mian ZENG, Wuhan (CN)

(21) Appl. No.: 16/152,274

(22) Filed: Oct. 4, 2018

Related U.S. Application Data
(63) Continuation of application No. PCT/CN2018/089414, filed on May 31, 2018.

(30) Foreign Application Priority Data
Apr. 18, 2018 (CN) 201810350792.3

(51) Int. Cl. H01L 51/52; H01L 51/00; H01L 51/56

(52) U.S. Cl. CPC H01L 51/5256; H01L 51/0097; H01L 2251/5338; H01L 51/56; H01L 51/0018

(57) ABSTRACT

Disclosed is a encapsulation structure of an organic light emitting diode, comprising: a substrate; an organic light emitting diode element formed on the substrate; a first organic thin film layer formed on the organic light emitting diode element, wherein the first organic thin film layer comprises a plurality of protrusion structures arranged at intervals; a first inorganic thin film layer formed on the substrate, the organic light emitting diode element, and the first organic thin film layer; a second organic thin film layer formed on the first inorganic thin film layer; and a second inorganic thin film layer formed on the second organic thin film layer. The encapsulation structure and the encapsulating method can enhance the anti-bending performance of the encapsulation structure of the organic light emitting diode, prolong the path of the water and oxygen entering the organic light emitting diode, and improve the encapsulation result.

### CROSS-REFERENCE TO RELATED APPLICATION

This application is a continuing application of PCT Patent Application No. PCT/CN2018/089414 entitled “Encapsulation structure of organic light emitting diode and encapsulating method”, filed on May 31, 2018, which claims priority to Chinese Patent Application No. 201810350792.3, filed on Apr. 18, 2018, both of which are hereby incorporated in its entireties by reference.

### FIELD OF THE INVENTION

The present invention relates to a display manufacturing field, and more particularly to a encapsulation structure of an organic light emitting diode and a encapsulating method.

### BACKGROUND OF THE INVENTION

The Organic Light Emitting Display (OLED) possesses many outstanding properties of self-illumination, low driving voltage, high luminescence efficiency, short response time, high clarity and contrast, applicability of flexible display and large scale full color display. The OLED is considered as the most potential display device.

The luminescent material in OLED devices is usually a polymer or organic small molecules. The cathode material is usually an active metal with a low work function, such as magnesium aluminum, etc. These luminescent materials and cathode materials are very sensitive to moisture and oxygen, and water/oxygen permeation can greatly reduce the lifetime of OLED devices. In order to achieve the commercialization of the requirements for the service life and stability of OLED devices, the requirements for the encapsulating result of OLED devices are very high. Therefore, the encapsulation plays a very important role in the production of OLED devices and is one of the key factors affecting the yield of the products.

The existing encapsulating technologies mainly are the following two ways: A, cover-plate encapsulating technology: applying a UV-curable sealant on a encapsulation glass/metal, or applying the sealant and a desiccant, and then curing the device to provide a relatively confined environment for a light-emitting device, thus blocking permeation of water and oxygen. B, laser encapsulating technology: applying glass glue on the encapsulation glass, for becoming a glass powder after solvent is volatile, and after the substrate is evaporated and is assembled with the encapsulation cover plate, the laser is used for melting the glass powder to realize adhesion. The aforesaid two encapsulating technologies can achieve effective water/oxygen barrier results, but increase the thickness and weight of the device, which is not conducive to the production of flexible OLEDs.

The existing encapsulation structure of a flexible OLED is shown in FIG. 3. After the OLED device 92 is prepared on the substrate 91, an inorganic layer 93 is deposited on the OLED device by chemical vapor deposition (CVD), and then an organic layer 94 is formed by the inject printing (IJP) method. Finally, an inorganic layer 95 is prepared by CVD deposition for a thin film. The technical problem of the encapsulation structure for a flexible OLED is: since the encapsulation thickness of the whole thin film is in a micrometer range, and the inorganic layer 93 is extremely easy to be broken during bending, water and oxygen will permeate the OLED device through this breakage to age the OLED device, so that the bending resistance of the encapsulation portion of the flexible OLED device is deteriorated.

### SUMMARY OF THE INVENTION

An objective of the present invention is to provide a encapsulation structure of an organic light emitting diode and a encapsulating method, which can enhance the anti-bending performance of the encapsulation structure of the organic light emitting diode, prolong the path of the water and oxygen entering the organic light emitting diode, and improve the encapsulation result.

For solving the aforesaid technical issue, the embodiment of present invention provides a encapsulation structure of an organic light emitting diode, comprising: a substrate; an organic light emitting diode element formed on the substrate; a first organic thin film layer formed on the organic light emitting diode element, wherein the first organic thin film layer comprises a plurality of protrusion structures arranged at intervals; a first inorganic thin film layer formed on the substrate, the organic light emitting diode element, and the first organic thin film layer; a second organic thin film layer formed on the first inorganic thin film layer; and a second inorganic thin film layer formed on the second organic thin film layer.

The plurality of protrusion structures arranged at intervals of the first organic thin film layer are formed by exposure and development processes; the first inorganic thin film layer is formed on the plurality of protrusion structures of the first organic thin film layer and on surface regions of the organic light emitting diode element corresponding to the intervals between the plurality of protrusion structures of the first organic thin film layer.

The second organic film layer is flattening structure for buffering.

The second organic thin film layer is formed with a plurality of grooves arranged at intervals by exposure and development processes on the second organic thin film layer, and the second inorganic thin film layer is a layer structure having a plurality of protrusions arranged at intervals.

The encapsulation structure of the organic light emitting diode further comprises a third organic thin film layer formed on the second inorganic thin film layer for buffering and flattening, and a third inorganic thin film layer formed on the third organic thin film layer.

The first inorganic thin film layer and the second inorganic thin film layer are respectively made of a silicon oxide material or a nitrogen oxide material; the first organic thin film layer and the second organic thin film layer are made of a high molecular polymer material or a resin material, respectively.

For solving the aforesaid technical issue, the present invention provides a encapsulation structure of an organic light emitting diode, comprising; a substrate; an organic light emitting diode element formed on the substrate; a first organic thin film layer formed on the organic light emitting diode element, wherein the first organic thin film layer comprises a plurality of protrusion structures arranged at intervals; a first inorganic thin film layer formed on the substrate, the organic light emitting diode element, and the first organic thin film layer; a second organic thin film layer formed on the first inorganic thin film layer; and a second inorganic thin film layer formed on the second organic thin film layer, wherein the second organic thin film layer is formed with a plurality of grooves arranged at intervals by exposure and development processes on the second organic thin film layer, and the second inorganic thin film layer is a layer structure having a plurality of protrusions arranged at intervals; the encapsulation structure of the organic light emitting diode further comprises a third organic thin film layer formed on the second inorganic thin film layer for buffering and flattening, and a third inorganic thin film layer formed on the third organic thin film layer.

The plurality of protrusion structures arranged at intervals of the first organic thin film layer are formed by exposure and development processes; the first inorganic thin film layer is formed on the plurality of protrusion structures of the first organic thin film layer and on surface regions of the organic light emitting diode element corresponding to the intervals between the plurality of protrusion structures of the first organic thin film layer; the second organic film layer is flattening structure for buffering.

The first inorganic thin film layer and the second inorganic thin film layer are respectively made of a silicon oxide material or a nitrogen oxide material; the first organic thin film layer and the second organic thin film layer are made of a high molecular polymer material or a resin material, respectively.

For solving the aforesaid technical issue, the present invention further provides a encapsulating method of an organic light emitting diode, comprising: preparing an organic light emitting diode element on a substrate; forming a first organic thin film layer on the organic light emitting diode element by exposure and development processes, wherein the first organic thin film layer comprises a plurality of protrusion structures arranged at intervals; depositing a first inorganic thin film layer on the substrate, the organic light emitting diode element, and the first organic thin film layer; preparing a second organic thin film layer on the first inorganic thin film layer; and depositing a second inorganic thin film layer on the second organic thin film layer.

The first inorganic thin film layer is formed on the plurality of protrusion structures of the first organic thin film layer and on surface regions of the organic light emitting diode element corresponding to the intervals between the plurality of protrusion structures of the first organic thin film layer.

Preparing the second organic thin film layer on the first inorganic thin film layer comprises: coating the second organic thin film layer on the first inorganic thin film layer for buffering and flattening; or preparing the second organic thin film layer on the first inorganic thin film layer comprises: preparing an organic thin film layer on the first inorganic thin film layer by coating or inject printing (IJP); implementing exposure and development processes to the organic thin film layer to form the second organic thin film layer having a plurality of grooves arranged at intervals.

After depositing the second inorganic thin film layer on the second organic thin film layer, the encapsulating method further comprises: coating a third organic thin film layer on the second inorganic thin film layer for buffering and flattening; depositing a third inorganic thin film layer on the third organic thin film layer.

Preparing the second organic thin film layer on the first inorganic thin film layer comprises: coating the second organic thin film layer on the first inorganic thin film layer for buffering and flattening; or preparing the second organic thin film layer on the first inorganic thin film layer comprises: preparing an organic thin film layer on the first inorganic thin film layer by coating or inject printing (IJP); implementing exposure and development processes to the organic thin film layer to form the second organic thin film layer having a plurality of grooves arranged at intervals, wherein after depositing the second inorganic thin film layer on the second organic thin film layer, the encapsulating method further comprises: coating a third organic thin film layer on the second inorganic thin film layer for buffering and flattening; depositing a third inorganic thin film layer on the third organic thin film layer.

The implementation the encapsulation structure and encapsulating method of the organic light emitting diode provided by the present invention possesses the following benefits: since the first inorganic thin film layer formed on the substrate, the organic light emitting diode element, and the first organic thin film layer comprises a plurality of protrusion structures arranged at intervals, the path of water and oxygen entering the organic light emitting diode element is prolonged. Meanwhile, the inorganic thin film layer can be prevented from being subjected to an excessive stress due to flexible bending, and the water-oxygen infiltration occurs. The anti-bending performance of the encapsulation structure of the organic light emitting diode can be enhanced in advance.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a cross-sectional view diagram of the first embodiment of a encapsulation structure of an organic light emitting diode according to the present invention.

FIG. 2 is a cross-sectional view diagram of the second embodiment of a encapsulation structure of an organic light emitting diode according to the present invention.

FIG. 3 is a cross-sectional view diagram of a encapsulation structure of an organic light emitting diode according to the prior art.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

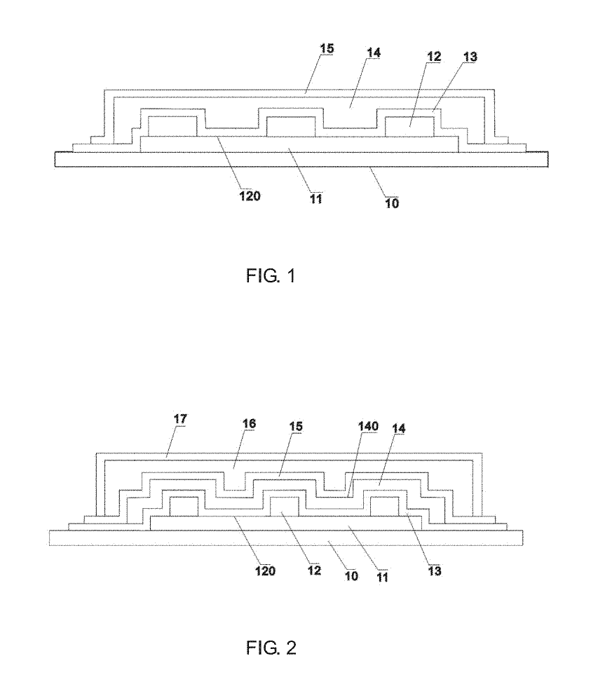

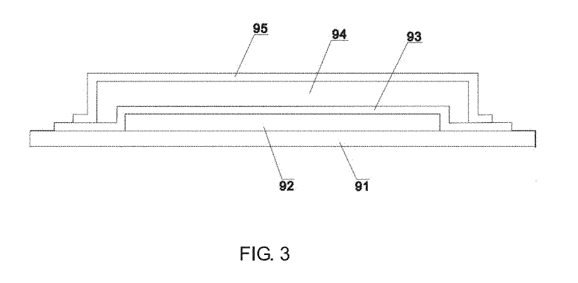

As shown in FIG. 1 it shows the first embodiment of a encapsulation structure of an organic light emitting diode according to the present invention.

The encapsulation structure of the organic light emitting diode in this embodiment comprises: a substrate 10 and an organic light emitting diode element 11 formed on the substrate 10.

The organic light emitting diode element 11 generally comprises: a substrate, an anode, a Hole Injection Layer, a Hole Transporting Layer, an emitting material layer, an Electron Transport Layer, an Electron Injection Layer and a cathode. The principle of the organic light emitting diode element 11 is that the illumination generates due to the carrier injection and recombination under the electric field driving of the semiconductor material and the organic semiconductor illuminating material.

Specifically, the ITO electrode and the metal electrode are respectively employed as the anode and the cathode of the organic light emitting diode element 11. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. After the radiation, visible light is emitted.

The encapsulation structure of the organic light emitting diode further comprises a first organic thin film layer 12 formed on the organic light emitting diode element 11. The first organic thin film layer 12 is made of a high molecular polymer material or a resin material. In this embodiment, the first organic film layer 12 comprises a plurality of protrusion structures, and the plurality of protrusion structures is arranged at intervals.

In this embodiment, the plurality of protrusion structures arranged at intervals of he first organic thin film layer 12 is realized as follows: the plurality of protrusion structures is formed by exposing and developing the organic thin film layer with a mask or half tone mask (HTM).

The encapsulation structure of the organic light emitting diode further comprises: a first inorganic thin film layer 13 formed on the substrate 10, the organic light emitting diode element 11 and the first organic thin film layer 12. In this embodiment, the first inorganic thin film layer 13 is formed on the plurality of protrusion structures of the first organic thin film layer 12 and on surface regions of the organic light emitting diode element 11 corresponding to the intervals 12 between the plurality of protrusion structures. The first inorganic thin film layer 13 is a continuous film structure and is prepared by depositing a thin film by chemical vapor deposition (CVD), which is coated on lateral sides of the organic light emitting diode element 11, on the plurality of protrusion structures of the first organic thin film layer 12 and on surface regions of the organic light emitting diode element 11 corresponding to the intervals 12 between the plurality of protrusion structures.

The first inorganic thin film layer 13 is made of a silicon oxide material or a nitrogen oxide material for forming a water-oxygen barrier layer.

Furthermore, the encapsulation structure of the organic light emitting diode further comprises: a second organic thin film layer 14 formed on the first inorganic thin film layer 13. In this embodiment, the second organic thin film layer 14 is made of a high molecular polymer material or a resin material. The function thereof is: by covering the pinholes or foreign body defects generated during the preparation of the first inorganic thin film layer 13, the stress between the inorganic thin film layers can be further released.

Furthermore, the encapsulation structure of the organic light emitting diode further comprises: a second inorganic thin film layer 15 formed on the second organic thin film layer 14. The second inorganic thin film layer 15 is made of a silicon oxide material or a nitrogen oxide material for forming a water-oxygen barrier layer.

The function of the first organic thin film layer 12 and the first inorganic thin film layer 13 as a whole to form the plurality of protrusion structures is: the path of water and oxygen entering the organic light emitting diode element 11 is prolonged. Thus, the inorganic thin film layer can be prevented from being subjected to an excessive stress due to flexible bending in the conventional structure, and the situation of water-oxygen infiltration may easily occur. The anti-bending performance of the encapsulation structure of the organic light emitting diode can be enhanced.

As shown in FIG. 2, it shows the second embodiment of a encapsulation structure of an organic light emitting diode according to the present invention.

The difference between the encapsulation structure of the organic light emitting diode in the present embodiment and the aforesaid first embodiment is that the second organic thin film layer 14 is formed with a plurality of grooves 140 arranged at intervals by exposure and development processes thereon, so that the second inorganic thin film layer 14 is provided with the plurality of protrusions arranged at intervals. In practical, the second organic thin film layer 14 may be exposed and developed by a mask or a HTM mask to form the plurality of protrusions arranged at intervals.

The second inorganic thin film layer 15 is a continuous film structure and is prepared by depositing a thin film by chemical vapor deposition (CVD), which is coated on the first inorganic thin film layer 13, on the second organic thin film layer 14 and on the plurality of grooves 140 formed on the second organic thin film layer 14.

Furthermore, the encapsulation structure of the organic light emitting diode further comprises a third organic thin film layer 16 formed on the second inorganic thin film layer 15 for buffering and flattening, and a third inorganic thin film layer 17 formed on the third organic thin film layer 16. In this embodiment, the third organic thin film layer 16 is made of a high molecular polymer material or a resin material. The third inorganic thin film layer 17 is made of a silicon oxide material or a nitrogen oxide material for forming a water-oxygen barrier layer.

In this embodiment, the second organic thin film layer 14 and the second inorganic thin film layer 15 are added, the path of water and oxygen entering the organic light emitting diode element 11 is prolonged in advance. Thus, the inorganic thin film layer can be prevented from being subjected to an excessive stress due to flexible bending in the conventional structure, and the situation of water-oxygen infiltration may easily occur. The anti-bending performance of the encapsulation structure of the organic light emitting diode can be enhanced.

The present invention further discloses a encapsulating method of an organic light emitting diode, comprising: preparing an organic light emitting diode element 11 on a substrate 10. The organic light emitting diode element 11 generally comprises: a substrate, an anode, a Hole Injection Layer, a Hole Transporting Layer, an emitting material layer, an Electron Transport Layer, an Electron Injection Layer and a cathode. The principle of the organic light emitting diode element 11 is that the illumination generates due to the carrier injection and recombination under the electric field driving of the semiconductor material and the organic semiconductor illuminating material.

Specifically, the ITO electrode and the metal electrode are respectively employed as the anode and the cathode of the organic light emitting diode element 11. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. After the radiation, visible light is emitted.

Furthermore, the encapsulating method of the organic light emitting diode further comprises: preparing a first organic thin film layer 12 on the organic light emitting diode element 11 with a high molecular polymer material or a resin material. The first organic film layer 12 comprises a plurality of protrusion structures, and the plurality of protrusion structures is arranged at intervals. The plurality of protrusion structures arranged at intervals can be formed with a mask or half tone mask (HTM).

The first inorganic thin film layer 13 is deposited on the substrate, the organic light emitting diode element and the first organic thin film layer 12; the first inorganic thin film layer 13 is prepared by chemical vapor deposition (CVD), which is coated on lateral sides of the organic light emitting diode element 11, on the plurality of protrusion structures of the first organic thin film layer 12 and on surface regions of the organic light emitting diode element 11 corresponding to the intervals 12 between the plurality of protrusion structures. The first inorganic thin film layer 13 is made of a silicon oxide material or a nitrogen oxide material for forming a water-oxygen barrier layer.

The function of the first organic thin film layer 12 and the first inorganic thin film layer 13 to form the plurality of protrusion structures is: the path of water and oxygen entering the organic light emitting diode element 11 is prolonged. Thus, the inorganic thin film layer can be prevented from being subjected to an excessive stress due to flexible bending in the conventional structure, and the situation of water-oxygen infiltration may easily occur. The anti-bending performance of the encapsulation structure of the organic light emitting diode can be enhanced.

The encapsulating method of the organic light emitting diode further comprises: coating a second organic thin film layer 14 on the first inorganic thin film layer 13 and depositing a second inorganic thin film layer 15 on the second organic thin film layer 14. In this embodiment, the second organic thin film layer 14 is made of a high molecular polymer material or a resin material. The function thereof is: by covering the pinholes or foreign body defects generated during the preparation of the first inorganic thin film layer 13, the stress between the inorganic thin film layers can be further released. The second inorganic thin film layer 15 is made of a silicon oxide material or a nitrogen oxide material for forming a water-oxygen barrier layer.

In this embodiment, the second organic film layer 14 is flattening structure for buffering.

In other embodiments, after preparing an organic thin film layer on the first inorganic thin film layer 13 by coating or inject printing (IJP), the organic thin film layer is exposed and developed to form the second organic thin film layer 14 having a plurality of grooves 140 arranged at intervals, so that the second organic thin film layer 14 is formed with a plurality of protrusion structures arranged at intervals. In practical, the plurality of protrusion structures arranged at intervals can be formed with a mask or half tone mask (HTM).

The second inorganic thin film layer 15 is prepared by depositing a thin film by chemical vapor deposition (CVD), which is coated on the first inorganic thin film layer 13, on the second organic thin film layer 14 and on the plurality of grooves 140 formed on the second organic thin film layer 14.

Furthermore, the encapsulating method of the organic light emitting diode further comprises: coating a third organic thin film layer 16 on the second inorganic thin film layer 15 for buffering and flattening, and depositing a third inorganic thin film layer 17 on the third organic thin film layer 16. In this embodiment, the third organic thin film layer 16 is made of a high molecular polymer material or a resin material. The third inorganic thin film layer 17 is made of a silicon oxide material or a nitrogen oxide material for forming a water-oxygen barrier layer.

In this embodiment, the second organic thin film layer 14 and the second inorganic thin film layer 15 are added, the path of water and oxygen entering the organic light emitting diode element 11 can be prolonged in advance. Thus, the inorganic thin film layer can be prevented from being subjected to an excessive stress due to flexible bending in the conventional structure, and the situation of water-oxygen infiltration may easily occur. The anti-bending performance of the encapsulation structure of the organic light emitting diode can be enhanced.

The implementation the encapsulation structure and encapsulating method of the organic light emitting diode provided by the present invention possesses the following benefits: since the first inorganic thin film layer formed on the substrate, the organic light emitting diode element, and the first organic thin film layer comprises a plurality of protrusion structures arranged at intervals, the path of water and oxygen entering the organic light emitting diode element is prolonged. Meanwhile, the inorganic thin film layer can be prevented from being subjected to an excessive stress due to flexible bending, and the water-oxygen infiltration occurs. The anti-bending performance of the encapsulation structure of the organic light emitting diode can be enhanced in advance.

What is claimed is:

1. A encapsulation structure of an organic light emitting diode, comprising:
a substrate;
an organic light emitting diode element formed on the substrate;
a first organic thin film layer formed on the organic light emitting diode element, wherein the first organic thin film layer comprises a plurality of protrusion structures arranged at intervals;
a first inorganic thin film layer formed on the substrate, the organic light emitting diode element, and the first organic thin film layer;
a second organic thin film layer formed on the first inorganic thin film layer; and
a second inorganic thin film layer formed on the second organic thin film layer.

2. The encapsulation structure of the organic light emitting diode according to claim 1, wherein the plurality of protrusion structures arranged at intervals of the first organic thin film layer are formed by exposure and development processes; the first inorganic thin film layer is formed on the plurality of protrusion structures of the first organic thin film layer and on surface regions of the organic light emitting diode element corresponding to the intervals between the plurality of protrusion structures of the first organic thin film layer.

3. The encapsulation structure of the organic light emitting diode according to claim 1, wherein the second organic film layer is flattening structure for buffering.

4. The encapsulation structure of the organic light emitting diode according to claim 2, wherein the second organic film layer is flattening structure for buffering.

5. The encapsulation structure of the organic light emitting diode according to claim 2, wherein the second organic thin film layer is formed with a plurality of grooves arranged at intervals by exposure and development processes on the second organic thin film layer, and the second inorganic thin film layer is a layer structure having a plurality of protrusions arranged at intervals.

6. The encapsulation structure of the organic light emitting diode according to claim 5, further comprising a third organic thin film layer formed on the second inorganic thin film layer for buffering and flattening, and a third inorganic thin film layer formed on the third organic thin film layer.

7. The encapsulation structure of the organic light emitting diode according to claim 1, wherein the first inorganic thin film layer and the second inorganic thin film layer are respectively made of a silicon oxide material or a nitrogen oxide material;
the first organic thin film layer and the second organic thin film layer are made of a high molecular polymer material or a resin material, respectively.

8. A encapsulation structure of an organic light emitting diode, comprising:
a substrate;
an organic light emitting diode element formed on the substrate;
a first organic thin film layer formed on the organic light emitting diode element, wherein the first organic thin film layer comprises a plurality of protrusion structures arranged at intervals;
a first inorganic thin film layer formed on the substrate, the organic light emitting diode element, and the first organic thin film layer;
a second organic thin film layer formed on the first inorganic thin film layer; and
a second inorganic thin film layer formed on the second organic thin film layer, wherein the second organic thin film layer is formed with a plurality of grooves arranged at intervals by exposure and development processes on the second organic thin film layer, and the second inorganic thin film layer is a layer structure having a plurality of protrusions arranged at intervals;
wherein the encapsulation structure of the organic light emitting diode further comprises a third organic thin film layer formed on the second inorganic thin film layer for buffering and flattening, and a third inorganic thin film layer formed on the third organic thin film layer.

9. The encapsulation structure of the organic light emitting diode according to claim 8, wherein the plurality of protrusion structures arranged at intervals of the first organic thin film layer are formed by exposure and development processes; the first inorganic thin film layer is formed on the plurality of protrusion structures of the first organic thin film layer and on surface regions of the organic light emitting diode element corresponding to the intervals between the plurality of protrusion structures of the first organic thin film layer;
wherein the second organic film layer is flattening structure for buffering.

10. The encapsulation structure of the organic light emitting diode according to claim 8, wherein the first inorganic thin film layer and the second inorganic thin film layer are respectively made of a silicon oxide material or a nitrogen oxide material;
the first organic thin film layer and the second organic thin film layer are made of a high molecular polymer material or a resin material, respectively.

11. The encapsulation structure of the organic light emitting diode according to claim 9, wherein the first inorganic thin film layer and the second inorganic thin film layer are respectively made of a silicon oxide material or a nitrogen oxide material;
the first organic thin film layer and the second organic thin film layer are made of a high molecular polymer material or a resin material, respectively.

12. A encapsulating method of an organic light emitting diode, comprising:
preparing an organic light emitting diode element on a substrate;
forming a first organic thin film layer on the organic light emitting diode element by exposure and development processes, wherein the first organic thin film layer comprises a plurality of protrusion structures arranged at intervals;
depositing a first inorganic thin film layer on the substrate, the organic light emitting diode element, and the first organic thin film layer;
preparing a second organic thin film layer on the first inorganic thin film layer; and
depositing a second inorganic thin film layer on the second organic thin film layer.

13. The encapsulating method of the organic light emitting diode according to claim 12, wherein the first inorganic thin film layer is formed on the plurality of protrusion structures of the first organic thin film layer and on surface regions of the organic light emitting diode element corresponding to the intervals between the plurality of protrusion structures of the first organic thin film layer.

14. The encapsulating method of the organic light emitting diode according to claim 12, wherein preparing the second organic thin film layer on the first inorganic thin film layer comprises: coating the second organic thin film layer on the first inorganic thin film layer for buffering and flattening;
or preparing the second organic thin film layer on the first inorganic thin film layer comprises: preparing an organic thin film layer on the first inorganic thin film layer by coating or inject printing (IJP); implementing exposure and development processes to the organic thin film layer to form the second organic thin film layer having a plurality of grooves arranged at intervals.

15. The encapsulating method of the organic light emitting diode according to claim 12, wherein after depositing the second inorganic thin film layer on the second organic thin film layer, the encapsulating method further comprises:
coating a third organic thin film layer on the second inorganic thin film layer for buffering and flattening;
depositing a third inorganic thin film layer on the third organic thin film layer.

16. The encapsulating method of the organic light emitting diode according to claim 12, wherein preparing the second organic thin film layer on the first inorganic thin film layer comprises: coating the second organic thin film layer on the first inorganic thin film layer for buffering and flattening; or preparing the second organic thin film layer on the first inorganic thin film layer comprises: preparing the second organic thin film layer on the first inorganic thin film layer comprises: preparing an organic thin film layer on the first inorganic thin film layer by coating or inject printing (IJP); implementing exposure and development processes to the organic thin film layer to form the second organic thin film layer having a plurality of grooves arranged at intervals;
wherein after depositing the second inorganic thin film layer on the second organic thin film layer, the encapsulating method further comprises: coating a third organic thin film layer on the second inorganic thin film layer for buffering and flattening; depositing a third inorganic thin film layer on the third organic thin film layer.
